(19) United States
(12) Patent Application Publication
(10) Pub. No.: US 2006/0131070 A1
(43) Pub. Date: Jun. 22, 2006

(54) Power delivery mechanism

(76) Inventors: Hong W. Wong, Portland, OR (US); Alexander Waizman, Portland, OR (US); Hue V. Lam, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/014,134

(22) Filed: Dec. 16, 2004

(51) Int. Cl. H05K 1/11

(52) U.S. Cl. 174/261

(57) ABSTRACT

According to one embodiment, a system is disclosed. The system includes a power supply a printed circuit board (PCB). The PCB includes a voltage regulator and a bus bar to couple power from the power supply to the voltage regulator

### FIELD OF THE INVENTION

The present invention relates to computer systems; more particularly, the present invention relates to delivering power to a power sensitive system such as a computer system.

### BACKGROUND

Integrated circuit (IC) components are typically powered by voltage regulators located at a remote location. Particularly, the IC components and voltage regulators are typically mounted on a computer system motherboard. Power is typically delivered to the voltages regulators from a power supply via the motherboard. In order to deliver power, the motherboard allocates one or more layers for the routing of power leads.

Having to provide additional motherboard layers results in added costs in manufacturing the boards. In addition, for mobile computer systems such as notebooks, the additional layers result in a larger notebook size.

### BRIEF DESCRIPTION OF THE DRAWINGS

The invention is illustrated by way of example and not limitation in the figures of the accompanying drawings, in which like references indicate similar elements, and in which:

FIG. 1 is a block diagram of one embodiment of a computer system;

FIG. 2 illustrates a top view of one embodiment of a computer system motherboard;

FIG. 3 illustrates a cross section of one embodiment of a bus bar;

FIG. 4 illustrates a top view of one embodiment of the bus bar;

FIG. 5 illustrates a cross section of another embodiment of a bus bar;

FIG. 6 illustrates a top view of one embodiment of the bus bar;

FIG. 7 illustrates a cross section of yet another embodiment of a bus bar;

FIG. 8 illustrates a top view of one embodiment of the bus bar; and

FIG. 9 illustrates a cross section of a further embodiment of a bus bar.

### DETAILED DESCRIPTION

A power bus bar design is described. In the following detailed description of the present invention, numerous specific details are set forth in order to provide a thorough understanding of the present invention. However, it will be apparent to one skilled in the art that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

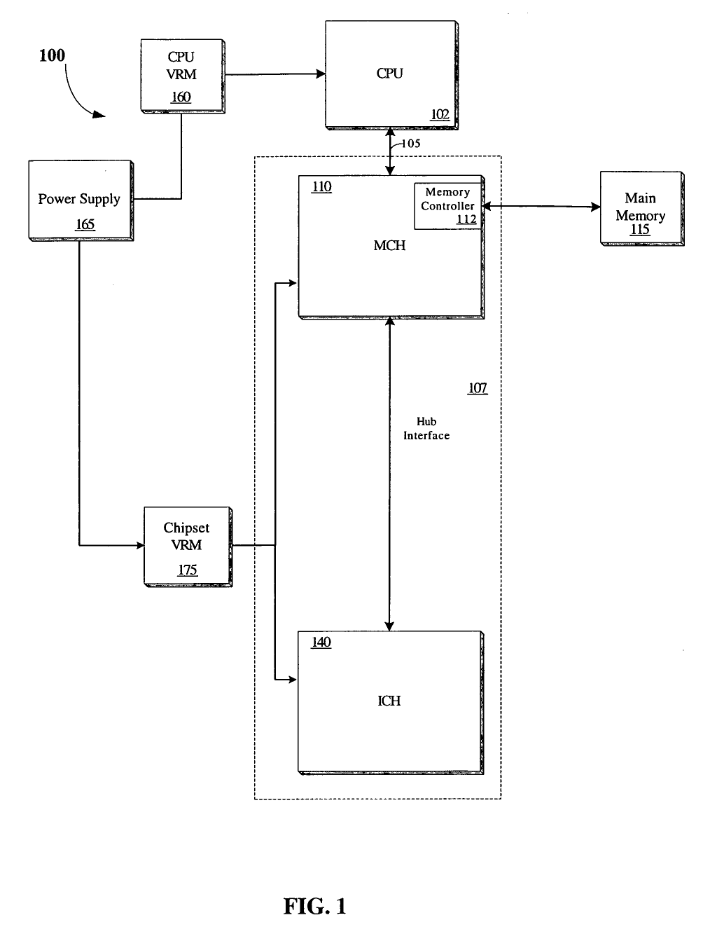

FIG. 1 is a block diagram of one embodiment of a computer system 100. According to one embodiment, computer system is a mobile computer (e.g., a laptop, or notebook computer). Computer system 100 includes a central processing unit (CPU) 102 coupled to bus 105. In one embodiment, CPU 102 is a processor in the Pentium® family of processors including the Pentium® II processor family, Pentium® III processors, and Pentium® IV processors available from Intel Corporation of Santa Clara, Calif. Alternatively, other CPUs may be used.

A chipset 107 is also coupled to bus 105. Chipset 107 includes a memory control hub (MCH) 110. MCH 110 may include a memory controller 112 that is coupled to a main system memory 115. Main system memory 115 stores data and sequences of instructions that are executed by CPU 102 or any other device included in system 100. In one embodiment, main system memory 115 includes dynamic random access memory (DRAM); however, main system memory 115 may be implemented using other memory types. Additional devices may also be coupled to bus 105, such as multiple CPUs and/or multiple system memories.

MCH 110 is coupled to an input/output control hub (ICH) 140 via a hub interface. ICH 140 provides an interface to input/output (I/O) devices within computer system 100. In addition, computer system 100 includes a power supply 165 and a multitude of voltage regulators that are used to provide power to various components within computer system 100. Particularly, CPU voltage regulator module (VRM) 160 provides voltage to CPU 102. VRM 175 supplies voltage for both MCH 110 and ICH 140 within chipset 107.

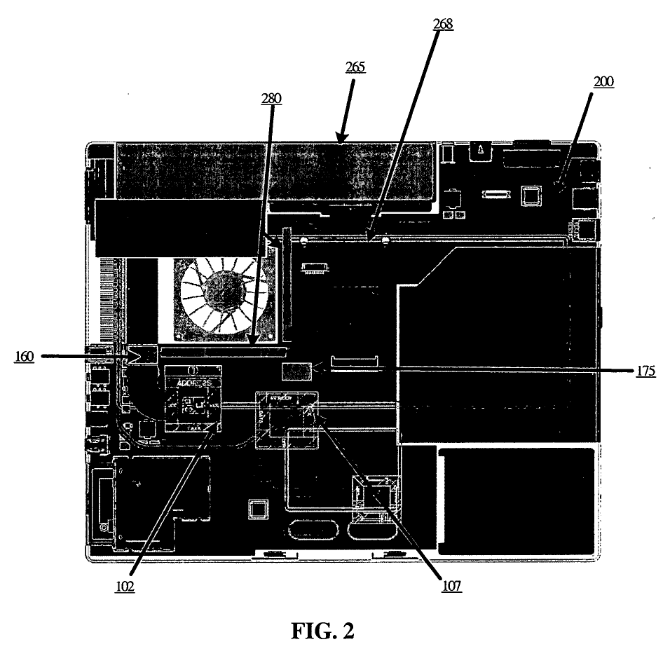

FIG. 2 illustrates a top view of one embodiment of computer system 100 in a motherboard 200 layout for a mobile computer system. Motherboard 200 is a printed circuit board (PCB) that includes the basic circuitry and IC components of computer system 100 mounted thereon. For instance, motherboard 200 includes CPU 102, chipset 107, VRM 160 and VRM 175.

In addition, motherboard 200 includes a battery pack 265, a battery connector 268 and a power bus bar 280. Battery pack 265 represents a power supply 165 that provides power to the components of motherboard 200. Connector 268 serves as an interface between battery pack 265 and motherboard 200 where the power is provided to motherboard 200.

Power bus bar 280 is a metal bar that feeds power to VRMs 160 and 175 from connector 268. According to one embodiment, bus bar 280 is implemented as two three inch bars that route the battery voltage (V_{BAT}) to VRM 160 and VRM 175, as shown in FIG. 2. However, in other embodiments, bus bar 280 may be implemented with other sizes and configurations. For example, bus bar 280 may include a single right angle bar rather than two separate bars.

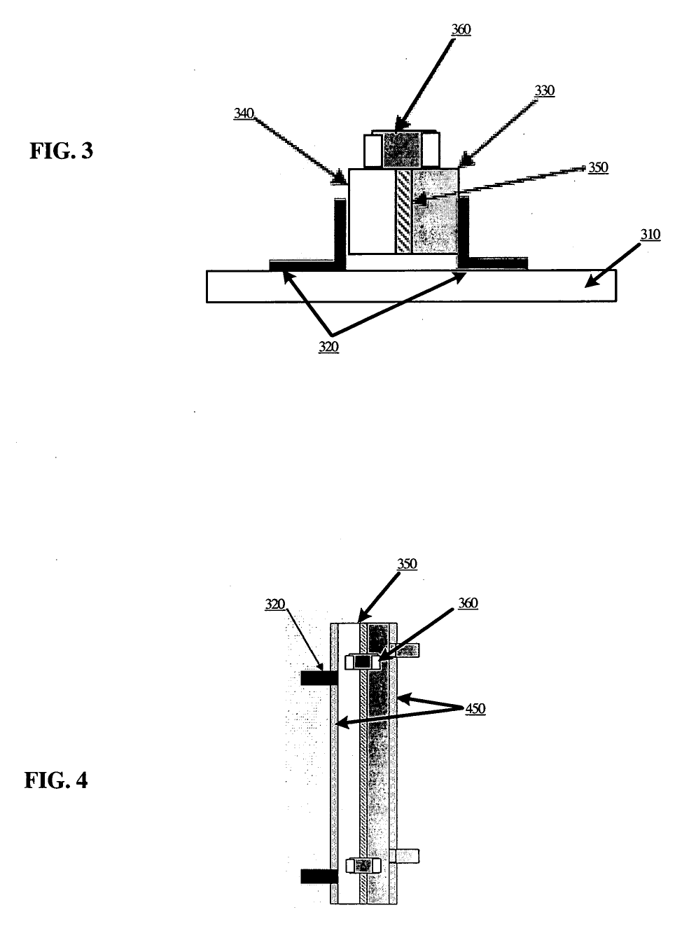

FIGS. 3 and 4 illustrate one embodiment of a power bus bar 280. Referring to FIG. 3, a cross section of bus bar 280 is shown coupled to a printed circuit board 310, such as motherboard 200. Bus bar 280 includes conductors 330 and 340, insulation layer 350 and one or more capacitors 360. Contacts 320 are also included to electrically connect conductors 340 and 350 to PCB 310. In one embodiment, PCB 310 supports the fan in and fan out of the current at both ends of bus bar 280.

As discussed above, bus bar 280 is made up of two sections of conductors 330 and 340 bonded together with an insulating material layer 350 in between. One conductor is for +Voltage, while the other is for the −Voltage. As a result, the back to back VCC & Ground arrangement minimizes the electromagnetic interference (EMI) from radiation out from the bus bar.

Capacitors 360 are mounted conductors 330 and 340 in order to reduce the inductance generated at bus bar 280, and to bypass high frequency noises. In other embodiments, capacitors 360 may be mounted on motherboard 200 near the terminal connections of bus bar 280.

FIG. 4 illustrates a top view of bus bar 280 shown in FIG. 3. In one embodiment, insulation coating 450 is added on the outside of each of conductors 330 and 340 to prevent the possibility of short circuiting. In a further embodiment, a high capacity capacitor (not shown) may be placed at the termination point of bus bar 280 to handle any occurrence of current surge.

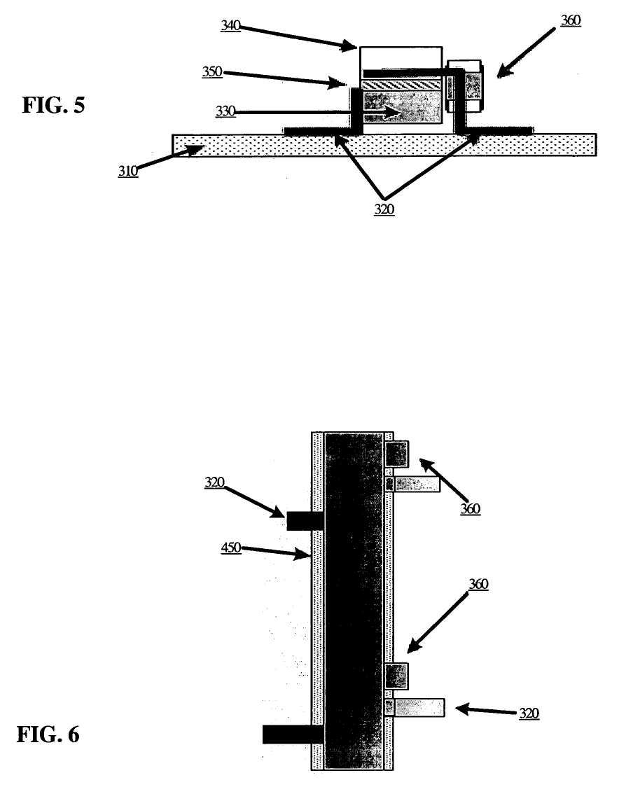

FIGS. 5 and 6 illustrate another embodiment of a power bus bar 280. FIG. 3 illustrates a cross section of one embodiment of bus bar 280 mounted on PCB 310. In this embodiment, bus bar 280 is rotated so that conductor 330 is mounted horizontally along PCB 310, while conductor 340 and insulation layer 350 are mounted directly above conductor 330. FIG. 6 illustrates a top view of bus bar 280 shown in FIG. 5.

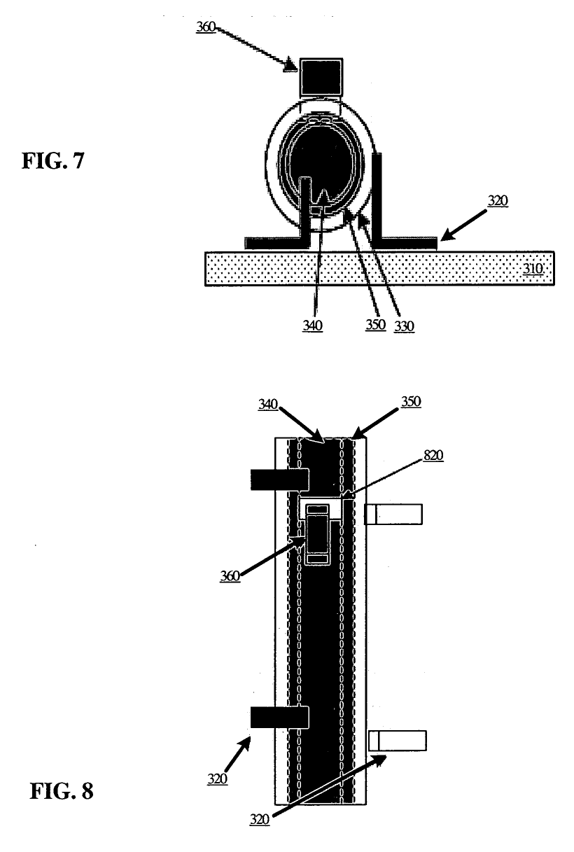

FIGS. 7 and 8 illustrate another embodiment of a power bus bar 280. FIG. 7 illustrates a cross section of one embodiment of bus bar 280 mounted on PCB 310. In this embodiment, bus bar 280 is in a cylindrical formation. The outer layer of the cylinder is conductor 330, with the innermost layer being conductor 340. Insulation layer 350 is between conductors 330 and 340. FIG. 8 illustrates a top view of bus bar 280 shown in FIG. 7. In this embodiment, an opening 820 is included to enable capacitor 360 to make contact with conductor 340.

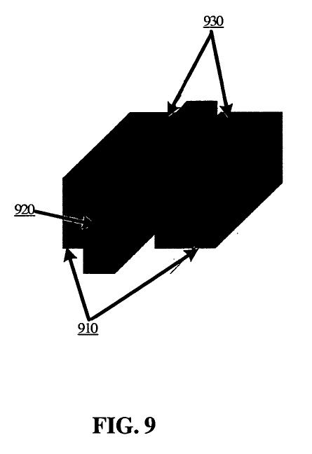

FIG. 9 illustrates yet another embodiment of bus bar 280. In this embodiment, bus bar 280 implements a GND-PWR-GND sandwich structure, where conductors 910 are used for ground and conductor 920 is for Vcc PWR. Insulation layers 930 are inserted between each conductor 910 and conductor 920. The multi-stacking design also allows a single buss bar to carry multiple voltage/power rails. In other embodiments, the GND-PWR layer count is increased to further increase the current carrying capability and to reduce inductance.

Note that although the above embodiments illustrate bus bar 280 having longitudinal shapes, other embodiments may feature bus bar 280 having different shapes (e.g., curve, right angle, etc.) to support different board placement and layout.

The bus bar mechanism creates an off-the-shelf component that can be mass produced at very low cost that can address various custom design requirements of notebook platform by allowing flexible placement of voltage regulators within the highly placement constrained notebook motherboard. Further, the bus bar enables the efficient use of motherboard layers, especially in a design with minimal layer counts.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as essential to the invention.

What is claimed is:

1. A system comprising:
a power supply; and
a printed circuit board (PCB), coupled to the power supply, having:
a voltage regulator; and
a bus bar to couple power from the power supply to the voltage regulator.

2. The system of claim 1 wherein the bus bar comprises:
a first conductor; and
a second conductor.

3. The system of claim 2 wherein the bus bar further comprises an insulation layer between the first conductor and the second conductor.

4. The system of claim 1 wherein the first conductor receives a positive voltage and the second conductor receives a negative voltage.

5. The system of claim 3 wherein the bus bar further comprises a capacitor mounted on the first conductor and the second conductor to minimize inductance.

6. The system of claim 5 wherein the bus bar further comprises:
a first contact to couple the first conductor to the PCB; and
a second contact to couple the second conductor to the PCB.

7. The system of claim 6 wherein the bus bar further comprises an external coating surrounding the first conductor and the second coating.

8. A method comprising:
receiving power at a motherboard from a power supply; and
transmitting the power from the motherboard to an integrated circuit (IC) via a bus bar.

9. The method of claim 8 further comprising transmitting the power from the motherboard to a voltage regulator prior to transmitting to the IC

10. The method of claim 9 wherein transmitting the power via the bus bar comprises:
transmitting a first voltage on a first conductor; and
transmitting a second voltage on a second conductor.

11. A computer system comprising:
a power supply;
a motherboard;
a central processing unit (CPU) mounted on the motherboard; and
a bus bar, mounted on the motherboard, to couple power from the power supply to the CPU.

12. The computer system of claim 11 wherein the bus bar comprises:
a first conductor; and
a second conductor.

13. The computer system of claim 12 wherein the bus bar further comprises an insulation layer between the first conductor and the second conductor.

14. The computer system of claim 11 wherein the first conductor receives a positive voltage and the second conductor receives a negative voltage.

15. The computer system of claim 13 wherein the bus bar further comprises a capacitor mounted on the first conductor and the second conductor to minimize inductance.

16. The computer system of claim 15 wherein the bus bar further comprises:
a first contact to couple the first conductor to the PCB; and
a second contact to couple the second conductor to the PCB.

17. The computer system of claim 16 wherein the bus bar further comprises an external coating surrounding the first conductor and the second coating.
